(19) United States
(12) Patent Application Publication
(10) Pub. No.: US 2025/0391688 A1
(43) Pub. Date: Dec. 25, 2025

(54) APPARATUS FOR OPENING AND CLOSING THE DOOR OF LOAD PORT MODULE

(71) Applicant: Hanwha Momentum Co., Ltd., Seongnam-si (KR)

(72) Inventors: Seong Dae BANG, Seongnam-si (KR); Dong Gu KIM, Seongnam-si (KR); Yun Chul SHIN, Seongnam-si (KR); Yeol Kwang KIM, Seongnam-si (KR); Yeon Hee CHOO, Seongnam-si (KR)

(73) Assignee: Hanwha Momentum Co., Ltd., Seongnam-si (KR)

(21) Appl. No.: 19/306,245

(22) Filed: Aug. 21, 2025

Related U.S. Application Data
(63) Continuation of application No. PCT/KR2025/001109, filed on Jan. 21, 2025.

(30) Foreign Application Priority Data
Feb. 13, 2024 (KR) 10-2024-0020522

(51) Int. Cl. H01L 21/677; E05F 15/00

(52) U.S. Cl. CPC H01L 21/67772; E05F 15/00; E05Y 2201/638; E05Y 2201/684; E05Y 2201/688; E05Y 2201/708; E05Y 2999/00

(57) ABSTRACT

A opening and closing apparatus of a load port module includes: a load port assembly including a mount on which a front opening unified pod (FOUP) is disposed, and a support that is arranged in a vertical direction with respect to the mount, and has an opening formed laterally with respect to the FOUP; a door assembly configured to selectively open and close the opening; and an opening and closing operator configured to open and close the door assembly on the load port assembly, wherein the opening and closing operator is configured to open the door assembly by tilting the door assembly at a set angle, and then linearly moving the door assembly.

### CROSS-REFERENCE TO RELATED APPLICATION(S)

This application is a continuation of International Application No. PCT/KR2025/001109, filed on Jan. 21, 2025, in the Korean Intellectual Property Receiving Office, which is based on and claims priority to Korean Patent Applications No. 10-2024-0020522, filed on Feb. 13, 2024, in the Korean Intellectual Property Office, the disclosures of which are incorporated by reference herein in their entireties.

### BACKGROUND

### 1. Field

The disclosure relates to an apparatus for opening and closing a door of a load port module, and more particularly, to an apparatus for opening and closing the door of a connected load port module, which is able to open and close a door positioned in the load port module for loading or unloading a front opening unified pod (FOUP) through an equipment front end module (EFEM).

### 2. Description of Related Art

In general, semiconductor wafers are processed through deposition, exposure, etching, and cleaning processes, among others. Semiconductors are fabricated by subjecting wafers to various processing steps.

Recently, semiconductor fabrication has been conducted in ways that improve process efficiency while increasing the semiconductor yield. For example, high-integration semiconductors are being produced by patterning fine circuits on wafers.

However, as fine patterning is applied to circuits, short circuits between circuits due to molecular contaminants are occurring more frequently. This short-circuit phenomenon in circuits has emerged as a problem that reduces semiconductor yield. Accordingly, active research and development is being conducted on devices that enhance cleanliness in each process step to maximize semiconductor yield.

For example, a device has been developed in which nitrogen gas is filled inside an equipment front end module (EFEM) that connects a load port module (LPM) and a transfer chamber, so that a front opening unified pod (FOUP) placed on the LPM is naturally enclosed in a nitrogen atmosphere.

However, in order to transfer wafers mounted in the FOUP from the LPM to the transfer chamber, the door of the LPM must first be slid and then vertically moved. For example, both an actuator for sliding the door and an actuator for vertically moving the door are needed, and as the size of the door increases, the capacity of the actuators also increases, posing a problem.

### SUMMARY

Various embodiments of the disclosure provide an opening and closing apparatus for a load port module that allows a door positioned in the load port module to be opened and closed using a single actuator, and that enables tilting and sliding movement to occur simultaneously during door opening.

Aspects of the invention are not limited to those mentioned above. The above and other aspects will become more apparent to one of ordinary skill in the art to which the disclosure pertains by referencing the detailed description of the invention given below.

According to an aspect of the disclosure, an opening and closing apparatus of a load port module, may include: a load port assembly including a mount including an upper surface, on which a front opening unified pod (FOUP) is disposed, and a support that is in a vertical direction with respect to the mount, and has an opening formed laterally with respect to the FOUP; a door assembly configured to selectively open and close the opening; and an opening and closing operator configured to open and close the door assembly on the load port assembly, wherein the opening and closing operator may be configured to open the door assembly by tilting the door assembly at a set angle, and then linearly moving the door assembly.

The opening and closing operator may include: a linear movement assembly configured to linearly move the door assembly on the load port assembly; and a tilting rotator configured to rotate the door assembly on the load port assembly in a set angle range.

The tilting rotator may include: a frame portion that extends from a lower portion of the door assembly and is rotatably connected to the linear movement assembly; an elastic assembly configured to provide an elastic restoring force in a direction in which the door assembly is opened between the linear movement assembly and the frame portion; and an angle block at a front end portion of the frame portion so as to selectively interfere with a roller on the support.

The angle block may include an inclined surface that contacts the roller during a process in which the door assembly is tilted at a set angle for opening the door assembly from a closed state.

The inclined surface may be formed in a range of about 30° to about 40°.

The linear movement assembly may include: a guide member in a vertical direction from the mount; a slider configured to slide on the guide member and to penetrate at least part of a slit formed in the support; and a power supplier that provides a driving force to the slider.

The slider may include: a rotation shaft configure to rotatably connect the tilting rotator to the linear movement assembly; a first stopper above the rotation shaft; and a second stopper below the rotation shaft.

The first stopper may be configured to elastically contact the frame portion based on the door assembly being closed, and the second stopper may be configured to elastically contact the frame portion based on the door assembly being open and the frame portion being tilted and rotated at a set angle.

In a state where the door assembly is open, an angle formed between the frame portion and an imaginary vertical line, which is formed by the second stopper, may be in a range of about 5° to about 10°.

The angle block may be height-adjustable on the frame portion.

Detailed aspects of other embodiments are included in the following description and drawings.

### BRIEF DESCRIPTION OF DRAWINGS

The detailed description of the embodiments of this application described below, as well as the summary described above, will be better understood when read in conjunction with the accompanying drawings. The drawings illustrate embodiments of the disclosure for illustrative purposes. However, it should be understood that the application is not limited to the exact arrangements and means shown.

FIG. 1 is a perspective view schematically illustrating a load port module according to an embodiment of the disclosure, as viewed from the front.

FIG. 2 is a perspective view illustrating a door opening and closing apparatus of the load port module in FIG. 1, as viewed from the rear.

FIG. 3 is a side view illustrating the door opening and closing apparatus of the load port module in FIG. 2.

FIG. 4 is a front view illustrating a linear movement assembly of the door opening and closing apparatus of the load port module in FIG. 3.

FIG. 5 is a partial enlarged view showing a tilting rotator of the door opening and closing apparatus of the load port module in FIG. 3.

FIG. 6 is a side view illustrating a partially open and tilted state of the door assembly in the load port module in FIG. 2.

FIG. 7 is a partial enlarged view illustrating the door opening and closing apparatus of the load port module in FIG. 6.

FIG. 8 is a reference view illustrating a fully open state of the door assembly in the load port module in FIG. 2.

### DETAILED DESCRIPTION

Hereinafter, embodiments of the disclosure will be described in detail with reference to the accompanying drawings. Advantages and features of the disclosure, and methods for achieving them, will become apparent with reference to the embodiments described in detail below in conjunction with the accompanying drawings. However, the disclosure is not limited to the embodiments disclosed below, but may be implemented in various different forms. These embodiments are merely provided to ensure the completeness of the disclosure and to fully convey the scope of the invention to those skilled in the art to which the disclosure pertains. The disclosure is defined only by the scope of the claims. Throughout the specification, like reference numerals denote like components.

The disclosure is susceptible to various modifications and includes various embodiments. Specific embodiments will be illustrated and described in the drawings.

However, this is not intended to limit the disclosure to such specific embodiments, and it should be understood to include all modifications, equivalents, and alternatives within the spirit and scope of the invention.

Terms including ordinal numbers such as first, second, etc., may be used to describe various components, but these terms are not intended to limit the components.

These terms are used solely to distinguish one component from another.

For example, a second component may be named a first component without departing from the scope of the invention, and similarly, a first component may be named a second component.

The term “and/or” includes any combination of one or more of the associated listed items or any of the listed items, whether individually or in combination.

When a component is said to be “connected to” or “coupled to” another component, it may be directly or indirectly connected or coupled to the other component via intervening components.

Conversely, when a component is described as being “directly connected to” or “directly coupled to” another component, it means that there are no intervening components.

The terms used in this application are for the purpose of describing particular embodiments only and are not intended to limit the invention.

Unless the context clearly indicates otherwise, the singular forms include the plural forms as well.

In this application, the terms “comprising” and “having” are intended to specify the presence of stated features, numbers, steps, operations, elements, components, or combinations thereof, without precluding the presence or addition of one or more other features, numbers, steps, operations, elements, components, or combinations thereof.

Embodiments will hereinafter be described with reference to the accompanying drawings, wherein the same or corresponding components, regardless of the drawing numbers, are assigned the same reference numbers, and redundant descriptions will be omitted for descriptive convenience.

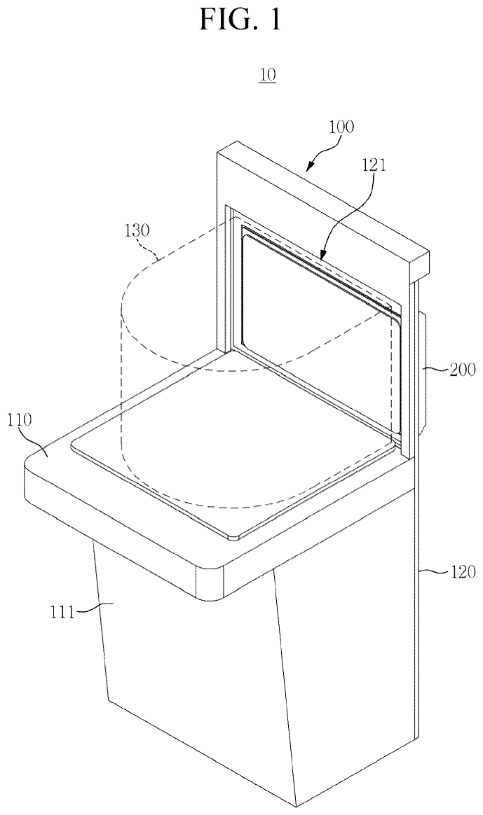

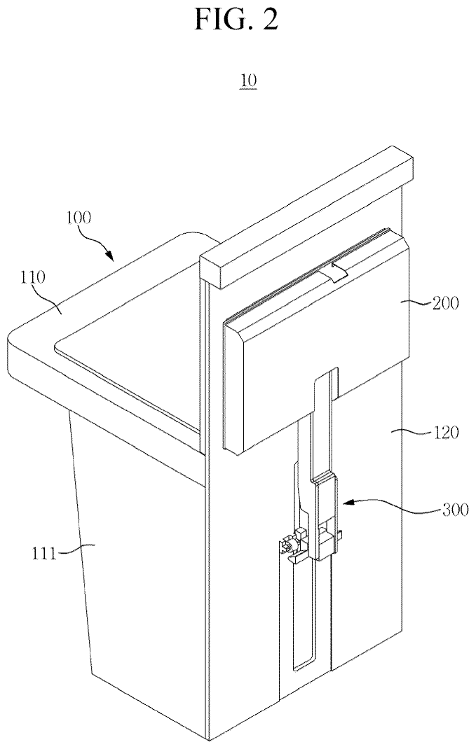

FIG. 1 is a perspective view schematically illustrating a load port module according to an embodiment of the disclosure, as viewed from the front. FIG. 2 is a perspective view illustrating a door opening and closing apparatus of the load port module in FIG. 1, as viewed from the rear.

Referring to FIGS. 1 and 2, a load port module 10 according to an embodiment of the disclosure may include a load port assembly 100, a door assembly 200, and an opening and closing operator 300.

First, the load port module 10 may be disposed in front of an equipment front end module (EFEM) and may identify information about wafers accommodated inside a front opening unified pod (FOUP) 130. Also, by opening the door assembly 200 such that the FOUP 130 and the door assembly 200 are in close contact with each other, wafer transfer may be performed. In FIGS. 1 and 2, only the load port module 10 is illustrated, and for the purpose of illustrating the opening and closing operator 300 from the rear of the load port module 10, as in FIG. 2, separate components of the EFEM (e.g., an ATM robot, aligner, etc.) are omitted.

The load port assembly 100 may include a mount 110 and a support 120.

The mount 110 may provide a region on which the FOUP 130 is placed. The mount 110 may be arranged in a horizontal direction.

The support 120 may be placed along a vertical direction at a side of the mount 110 and may be supported on an installation surface, on which the load port assembly 100 is installed. An opening 121 may be formed in an upper portion of the support 120 and an upper region of the mount 110, to correspond to the opening region of the FOUP 130. In a lower region of the mount 110 on the support 120, components of the opening and closing operator 300 may be arranged.

Although a single load port module 10 is illustrated and described in the drawings, a plurality of load port modules may be provided.

For example, the door assembly 200 may be placed or positioned on the rear surface of the support 120 to correspond to the opening 121. The door assembly 200 may open the opening 121 by tilting and linearly moving rearward relative to the support 120.

The opening and closing operator 300 may tilt and linearly move the door assembly 200. For example, the door assembly 200 may be tilted at a selected angle and rotated relative to the support 120, and then linearly moved. Since a single actuator is used for both tilting and linear movement in a coordinated manner, the number of actuators may be reduced. Moreover, by improving the tilting mechanism of the door assembly 200 through the opening and closing operator 300, it is possible to prevent the actuator size from increasing linearly with an increase in the size of the door assembly 200.

The structure and operational effects of the opening and closing operator 300 will hereinafter be described in detail.

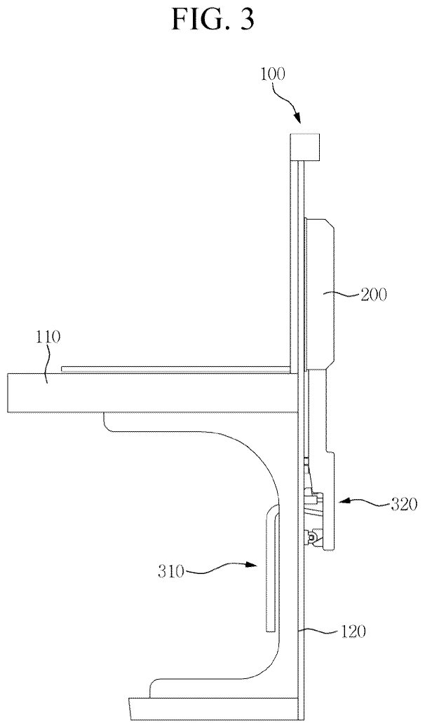

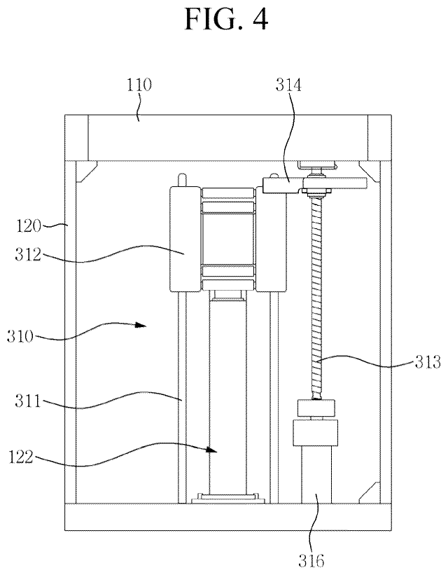

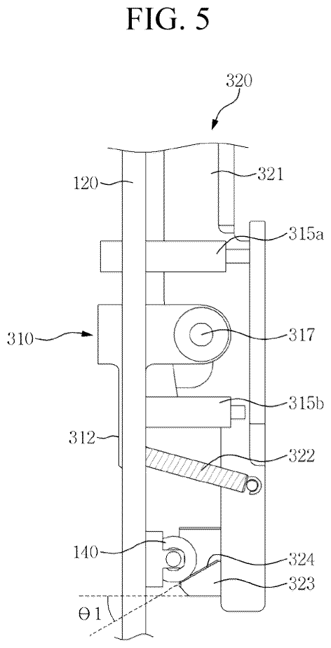

FIG. 3 is a side view illustrating the door opening and closing apparatus of the load port module in FIG. 2. FIG. 4 is a front view illustrating a linear movement assembly 310 of the door opening and closing apparatus of the load port module in FIG. 3. FIG. 5 is a partial enlarged view illustrating a tilting rotator 320 of the door opening and closing apparatus of the load port module in FIG. 3.

Referring to FIG. 3, the opening and closing operator 300 in FIG. 2 may include the linear movement assembly 310 and the tilting rotator 320. For example, in FIGS. 3 and 4, a cover 111 at a lower portion of the load port module 10 may have been removed.

The linear movement assembly 310 may be provided or positioned at a side of the support 120 of the load port assembly 100, and the tilting rotator 320 may be provided or positioned at another side of the support 120.

Referring to FIG. 4, the linear movement assembly 310 may include guide members 311, a slider 312, and a power supplier.

Two guide members 311 may be provided or positioned side by side along the vertical direction on a side surface of the support 120. For example, linear movement guides may be applied as the guide member 311.

The slider 312 may be installed to linearly move along the length direction of the guide members 311 on sides (e.g., opposite sides).

The power supplier may include an actuator 316 and a shaft 313.

The actuator 316 may provide a driving force or power to the shaft 313.

The shaft 313 may be arranged to interfere with (or may be engaged with) the slider 312.

For example, the shaft 313 may be rotated by receiving a driving force or power from the actuator 316, which is a motor, and a coupling member 314 may be coupled to engage with the shaft 313. The shaft 313 may penetrate the coupling member 314, and an external thread and an internal thread or an external gear and an internal gear may be formed. As the shaft 313 rotates, the coupling member 314 may convert the rotational motion of the shaft 313 into linear motion. The coupling member 314 may be coupled to a side of the slider 312, and the coupling member 314 and the slider 312 may linearly move on the guide members 311 in accordance with the rotation of the shaft 313. The shaft 313 may have a length that is equal to or greater than the linear movement range of the door assembly 200.

For example, a slit 122 may be formed in the support 120 to penetrate between the guide members 311 on sides (e.g., opposite sides). The slit 122 may be formed parallel to the length direction of the guide members 311 and may have at least a height range corresponding to the distance by which the door assembly 200 is spaced apart from the opening 121, or even greater.

Accordingly, a portion of the slider 312 may be arranged to penetrate the slit 122 and be coupled with the tilting rotator 320.

When a driving force or power is applied to the actuator 316, the shaft 313 may be rotated in a direction to lower the slider 312, and rotated in another direction to raise the slider 312. When the slider 312 descends (or moves downward), the tilting rotator 320 coupled thereto may simultaneously descend (or move downward), and when the slider 312 ascends (or moves upward), the tilting rotator 320 may simultaneously ascend (or move upward).

Referring to FIG. 5, the tilting rotator 320 may include a frame portion 321, an elastic assembly 322, and an angle block 323.

A first end portion of the frame portion 321 may be coupled to the door assembly 200, and a central region of the frame portion 321 may be coupled to a rotation shaft 317 that is exposed to another side of the support 120 by penetrating the slit 122 from the slider 312. Accordingly, the frame portion 321 may tilt within a set angular range with respect to the rotation shaft 317, and the door assembly 200 may also tilt at the same time.

The frame portion 321 may be formed or configured as a single structure by assembling a plurality of frames. In another example, the frame portion 321 may be implemented in a single steel pipe structure. In this embodiment, the frame portion 321 may include two opposing side plates, which are coupled to the door assembly 200 and the rotation shaft 317, respectively, and rear frames, which cover the back surfaces of the two opposing side plates and are coupled between the two opposing side plates to form a rear surface.

The elastic assembly 322 may include a spring and any elastic member, such as a rubber band, elastomeric pad, or a flexible bellows, not being limited thereto. A first end portion of the elastic assembly 322 may be coupled to the slider 312, and a second end portion of the elastic assembly 322 may be coupled to the frame portion 321. The elastic assembly 322 may provide an elastic restoring force that always pulls the frame portion 321 relative to the slider 312.

For example, the second end portion of the elastic assembly 322 may be coupled closer to a second end portion of the frame portion 321 relative to the rotation shaft 317 of the slider 312. Accordingly, referring to FIG. 5, tension may be applied such that the frame portion 321 may rotate clockwise about the rotation shaft 317 in the absence of an external force. In FIG. 5, since the angle block 323 is in contact with a roller 140, the elastic assembly 322 is illustrated in a stretched state with a selected interval (or selected distance) between the slider 312 and the frame portion 321.

The angle block 323 may be coupled to the second end portion of the frame portion 321.

The angle block 323 may be in contact with the roller 140 provided or positioned on the rear surface of the support 120. The angle block 323 may interfere with the roller 140 during the opening process of the door assembly 200 with the opening 121 in a closed state (or during the closing process of the door assembly 200), thereby performing a part in tilting rotation.

When the door assembly 200 is in a closed state where the frame portion 321 is vertically arranged relative to the installation surface, with the opening 121 in a closed state, an angle θ1 of an inclined surface 324 of the angle block 323 may be formed in a range of about 30° to about 40°. For example, in the state in FIG. 5, the angle θ1 formed by the inclined surface 324 with respect to the installation surface may be about 30°. The angle θ1 of the inclined surface 324 may vary according to the total length of the frame portion 321, the distance between the rotation shaft 317 and the angle block 323, and the tilt angle range of the door assembly 200.

The linear movement assembly 310 may include a first stopper 315a and a second stopper 315b.

The first and second stoppers 315a and 315b may be arranged to protrude from the slider 312 through the slit 122 toward the frame portion 321. In another example, each of the first and second stoppers 315a and 315b may be additionally provided or disposed on a protruding portion extending from the slider 312 toward of the frame portion 321 and may thus selectively contact the frame portion 321.

The first stopper 315a may be provided or positioned closer to a first end portion of the frame portion 321 relative to the rotation shaft 317 of the slider 312, and the second stopper 315b may be provided or positioned closer to a second end portion of the frame portion 321 relative to the rotation shaft 317 of the slider 312. Accordingly, referring to FIG. 5, the first stopper 315a may be located above the rotation shaft 317, and the second stopper 315b may be located below the rotation shaft 317.

In the closed state of the door assembly 200, the front end portion of the first stopper 315a may be arranged to contact the frame portion 321.

In the open state of the door assembly 200, the front end portion of the second stopper 315b may be arranged to contact the frame portion 321.

The first and second stoppers 315a and 315b may have a shock absorber function, thereby mitigating or reducing a selected impact during the process of each of the first and second stoppers 315a and 315b contacting the frame portion 321.

For example, the first stopper 315a may limit the counterclockwise rotation angle of the frame portion 321 by contacting the frame portion 321 while absorbing impact when the door assembly 200 is in close contact with the opening 121, e.g., in a fully closed state.

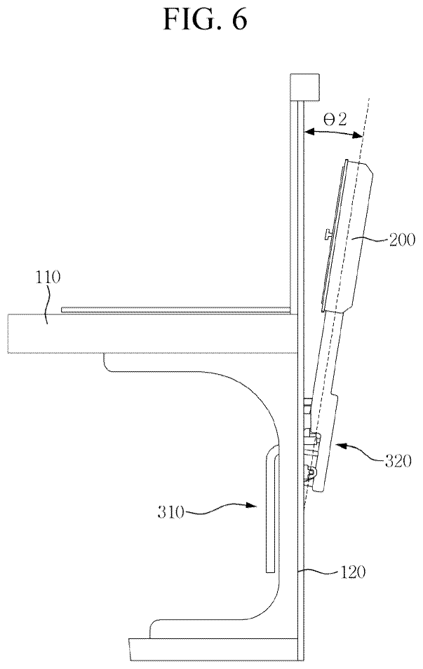

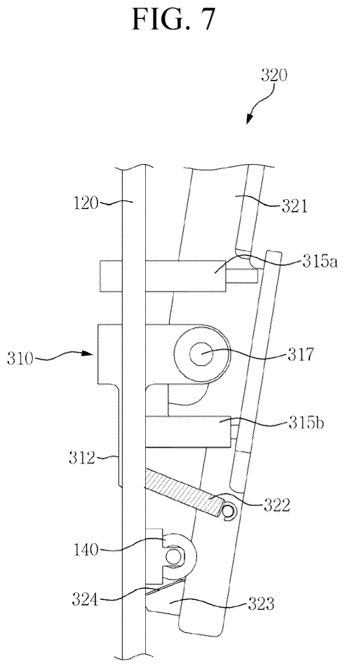

FIG. 6 is a side view illustrating a partially open and tilted state of the door assembly in the load port module in FIG. 2, and FIG. 7 is a partial enlarged view illustrating the door opening and closing apparatus of the load port module in FIG. 6.

When the actuator 316 operates to lower the slider 312 to open the door assembly 200, the frame portion 321 may tilt and rotate while descending.

When the frame portion 321 descends, the angle block 323 may also descend simultaneously, and the inclined surface 324 of the angle block 323 in contact with the roller 140 may rotate toward the rear surface of the support 120, thereby enabling tilting. Such rotation tilting may occur as the angle θ1 of the inclined surface 324 with respect to the installation surface decreases.

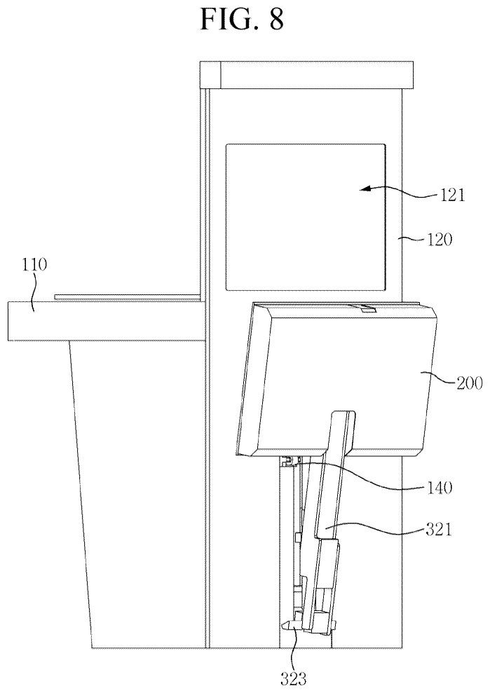

As illustrated in FIG. 7, during the opening of the door assembly (200 in FIG. 8), the frame portion 321 may be subjected to tension to rotate clockwise about the rotation shaft 317 by the elastic assembly 322, and as the contact angle formed between the angle block 323 and the roller 140 becomes smaller, tilting rotation of the frame portion 321 may be achieved along with the descent of the door assembly 200 and the opening and closing operator 300.

For example, since the second stopper 315b is arranged to contact the frame portion 321 in accordance with the set angle of the frame portion 321, the rotation of the frame portion 321 may be stopped upon contacting the second stopper 315b. Since the second stopper 315b has a shock absorber function, the second stopper 315b may reduce impact or noise between the frame portion 321 and the load port assembly 100 during the tilting rotation of the frame portion 321. Further, in the open state of the door assembly 200, the front end portion of the second stopper 315b may be placed in contact with the frame portion 321.

For example, an angle θ2 of the frame portion 321 with respect to the support 120 when the second stopper 315b contacts the frame portion 321 may be in a range of about 5° to about 10°. For example, the angle θ2 of the frame portion 321 may be set to about 5°. The angle θ2, by which the frame portion 321 is to tilt, may vary according to the thickness or size of the door assembly 200.

For example, the angle block 323 may be arranged such that its coupling height may be adjusted from the second end portion of the frame portion 321. This improves versatility by enabling adaptation to various diameters of the roller 140. For example, the angle block 323 may be configured to allow height adjustment relative to the frame portion 321, or the inclined surface 324 may be partially height-adjustable on the angle block 323. In another example, the position or height of the roller 140 may also be made adjustable to achieve a similar effect.

FIG. 8 is a reference view illustrating a fully open state of the door assembly in the load port module in FIG. 2.

FIG. 8 illustrates a state in which the door assembly 200 and the frame portion 321 descend to the lowermost end portion of the support 120, thereby fully opening.

For example, during the process in which the door assembly 200 and the frame portion 321 descend to the lowermost end portion of the support 120, the door assembly 200 may maintain the tilt angle formed from the initial stage of opening.

As such, when the opening 121 is fully open, wafers may be removed from inside the FOUP described above and transferred for other processes.

During the closing of the door assembly 200, the door assembly 200 and the frame portion 321 may linearly move upward (or ascend) in the vertical direction until the roller 140 and the angle block 323 come into contact again. From that point onward, tilting may be performed as the door assembly 200 continues to ascend until it is fully closed.

Accordingly, according to the door opening and closing apparatus of the load port module of the disclosure, tilting rotation and linear movement of the door assembly may be implemented using a single actuator. When the door assembly is open, tilting rotation may be performed first without horizontal sliding movement of the door assembly, and thus, the space required for opening the door assembly may be minimized. Moreover, since the door assembly may be opened even with a smaller-scale actuator, the installation space for the actuator may be minimized. Further, by implementing the angle block to be height-adjustable on the frame portion, it becomes easier to apply the door opening and closing apparatus of the load port module of the disclosure for different roller sizes or various door sizes.

According to the door opening and closing apparatus of a load port module of the disclosure, tilting rotation and linear movement of a door assembly may be implemented using a single actuator.

At the stage of the opening of the door assembly, since the door assembly first undergoes tilting rotation without sliding in a horizontal direction, the space required for opening the door assembly may be minimized.

Even with a smaller-scale actuator, the door assembly may be opened, thereby minimizing the installation space for the actuator.

Application to different roller sizes or to various door sizes may be facilitated by implementing the height of an angle block on a frame portion to be adjustable.

While the technical idea of the invention has been illustrated and described in detail with reference to specific embodiments, the disclosure is not limited to the specific configurations and operations of these embodiments. Various modifications may be made within the scope of the invention without departing from its spirit. Therefore, such modifications should be considered within the scope of the invention, and the scope of the invention should be determined by the appended claims.

What is claimed is:

1. An opening and closing apparatus of a load port module, comprising:
a load port assembly comprising:
a mount comprising an upper surface, on which a front opening unified pod (FOUP) is disposed, and
a support that is in a vertical direction with respect to the mount, and has an opening formed laterally with respect to the FOUP;
a door assembly configured to selectively open and close the opening; and
an opening and closing operator configured to open and close the door assembly on the load port assembly,
wherein the opening and closing operator is configured to open the door assembly by tilting the door assembly at a set angle, and then linearly moving the door assembly.

2. The opening and closing apparatus of claim 1, wherein the opening and closing operator comprises:
a linear movement assembly configured to linearly move the door assembly on the load port assembly; and
a tilting rotator configured to rotate the door assembly on the load port assembly in a set angle range.

3. The opening and closing apparatus of claim 2, wherein the tilting rotator comprises:
a frame portion that extends from a lower portion of the door assembly and is rotatably connected to the linear movement assembly;
an elastic assembly configured to provide an elastic restoring force in a direction in which the door assembly is opened between the linear movement assembly and the frame portion; and
an angle block at a front end portion of the frame portion so as to selectively interfere with a roller on the support.

4. The opening and closing apparatus of claim 3, wherein the angle block comprises an inclined surface that contacts the roller during a process in which the door assembly is tilted at a set angle for opening the door assembly from a closed state.

5. The opening and closing apparatus of claim 4, wherein the inclined surface is formed in a range of about 30° to about 40°.

6. The opening and closing apparatus of claim 3, wherein the linear movement assembly comprises:
a guide member in a vertical direction from the mount;
a slider configured to slide on the guide member and to penetrate at least part of a slit formed in the support; and
a power supplier that provides a driving force to the slider.

7. The opening and closing apparatus of claim 6, wherein the slider comprises:
a rotation shaft configured to rotatably connect the tilting rotator to the linear movement assembly;
a first stopper above the rotation shaft; and
a second stopper below the rotation shaft.

8. The opening and closing apparatus of claim 7, wherein:
the first stopper is configured to elastically contact the frame portion based on the door assembly being closed, and
the second stopper is configured to elastically contact the frame portion based on the door assembly being open and the frame portion being tilted and rotated at a set angle.

9. The opening and closing apparatus of claim 7, wherein in a state where the door assembly is open, an angle formed between the frame portion and an imaginary vertical line, which is formed by the second stopper, is in a range of about 5° to about 10°.

10. The opening and closing apparatus of claim 3, wherein the angle block is height-adjustable on the frame portion.
